(19) United States
(12) Patent Application Publication
(10) Pub. No.: US 2024/0106386 A1
(43) Pub. Date: Mar. 28, 2024

(54) PHOTOVOLTAIC MODULES INTEGRATED WITH BUILDING SIDING AND FENCING

(71) Applicant: GAF Energy LLC, Parsippany, NJ (US)

(72) Inventors: Richard Perkins, San Jose, CA (US); Thierry Nguyen, San Francisco, CA (US); Brian West, San Francisco, CA (US); Henry Pham, San Jose, CA (US)

(21) Appl. No.: 18/471,776

(22) Filed: Sep. 21, 2023

Related U.S. Application Data
(60) Provisional application No. 63/410,047, filed on Sep. 26, 2022.

(51) Int. Cl. H02S 20/26; H02S 40/36

(52) U.S. Cl. CPC H02S 20/26; H02S 40/36

(57) ABSTRACT

A system includes a plurality of photovoltaic modules installed in an array on an exterior wall of a structure. Each of the photovoltaic modules includes at least one solar cell, a first encapsulant encapsulating the at least one solar cell, and a frontsheet juxtaposed with the encapsulant. The frontsheet includes a glass layer. The system includes a plurality of siding panels installed on the exterior wall. The plurality of siding panels is adjacent to the plurality of photovoltaic modules.

### CROSS-REFERENCE TO RELATED APPLICATION

This application is a Section 111(a) application relating to and claiming the benefit of commonly-owned, co-pending U.S. Provisional Patent Application Ser. No. 63/410,047, filed Sep. 26, 2022, entitled “PHOTOVOLTAIC MODULES INTEGRATED WITH BUILDING SIDING,” the contents of each of which are incorporated herein by reference in its entirety.

### FIELD OF THE INVENTION

The present invention relates to photovoltaic systems and, more particularly, photovoltaic modules integrated with building siding and fencing.

### BACKGROUND

Photovoltaic modules are typically placed on building roofs to generate electricity.

### SUMMARY

In some embodiments, a system includes a plurality of photovoltaic modules installed on an exterior wall of a structure, wherein the photovoltaic modules are arranged in an array on the exterior wall, wherein each of the photovoltaic modules includes at least one solar cell, a first encapsulant encapsulating the at least one solar cell, wherein the first encapsulant includes a first surface and a second surface opposite the first surface, and a frontsheet juxtaposed with the first surface of the first encapsulant, wherein the frontsheet includes a glass layer; and a plurality of siding panels installed on the exterior wall, wherein the plurality of siding panels is adjacent to the plurality of photovoltaic modules.

In some embodiments, each of the plurality of photovoltaic modules includes a first end, a second end opposite the first end, a first edge extending from the first end to the second end, and a second edge opposite the first edge and extending from the first end to the second end, a headlap portion, wherein the headlap portion extends from the first end to the second end and from the first edge to a first location between the first edge and the second edge.

In some embodiments, each of the plurality of photovoltaic modules includes a side lap portion, and the second photovoltaic module overlays at least a part of the side lap of the first photovoltaic module.

In some embodiments, each of the plurality of photovoltaic modules includes a first end, a second end opposite the first end, a first edge extending from the first end to the second end, and a second edge opposite the first edge and extending from the first end to the second end, a headlap portion, wherein the headlap portion extends from the first end to the second end and from the first edge to a first location between the first edge and the second edge, and a side lap located at the first end, wherein the side lap includes a length extending from the first end to a second location between the first end and the second end.

In some embodiments, each of the plurality of photovoltaic modules is installed on the exterior wall by at least one fastener, and wherein the headlap portion is configured to receive the at least one fastener therethrough. In some embodiments, a first photovoltaic module of the plurality of photovoltaic modules is horizontally adjacent to a second photovoltaic module of the plurality of photovoltaic modules, and wherein a third photovoltaic module of the plurality of photovoltaic modules is vertically adjacent to the first photovoltaic module. In some embodiments, the first ends of the first and third photovoltaic modules are substantially aligned with each other, wherein the second ends of the first and third photovoltaic modules are substantially aligned with each other, wherein the first photovoltaic module overlays at least a part of the headlap portion of the third photovoltaic module.

In some embodiments, each of the plurality of photovoltaic modules is installed on the exterior wall by at least one fastener, and wherein the headlap portion is configured to receive the at least one fastener therethrough. In some embodiments, a first photovoltaic module of the plurality of photovoltaic modules is horizontally adjacent to a second photovoltaic module of the plurality of photovoltaic modules, and wherein a third photovoltaic module of the plurality of photovoltaic modules is vertically adjacent to the first photovoltaic module. In some embodiments, the first ends of the first and third photovoltaic modules are substantially aligned with each other, wherein the second ends of the first and third photovoltaic modules are substantially aligned with each other, wherein the first photovoltaic module overlays at least a part of the headlap portion of the third photovoltaic module, and wherein the second photovoltaic module overlays at least a part of the side lap of the first photovoltaic module.

In some embodiments, each of the plurality of photovoltaic modules includes an outer surface and an inner surface opposite the outer surface, and wherein the inner surface of the first photovoltaic module is attached to the outer surface of the third photovoltaic module. In some embodiments, the inner surface of the first photovoltaic module is attached to the outer surface of the third photovoltaic module by an adhesive. In some embodiments, the inner surface of the first photovoltaic module is attached to the outer surface of the third photovoltaic module by a clip. In some embodiments, each of the plurality of siding panels is installed substantially horizontally on the exterior wall, and wherein at least the third photovoltaic module overlays at least a portion of at least a first one of the plurality of siding panels.

In some embodiments, each of the plurality of siding panels includes a nailing strip and an exposed portion adjacent to the nailing strip, wherein the at least the third photovoltaic module overlays the nailing strip of the at least a first one of the plurality of siding panels, and wherein the exposed portion of the at least a first one of the plurality of siding panels is adjacent to the second edge of the at least the third photovoltaic module. In some embodiments, each of the plurality of photovoltaic modules includes a reveal portion, and wherein the exposed portion of at least a second one of the plurality of siding panels is substantially aligned with the reveal portion of the third photovoltaic module. In some embodiments, the exposed portion of at least a third one of the plurality of siding panels is substantially aligned with the reveal portion of the first photovoltaic module. In some embodiments, the exposed portion of each of the plurality of siding panels includes an interlocking flange, wherein the nailing strip of each of the plurality of siding panels includes a projection, and wherein the interlocking flange of the at least first one of the plurality of siding panels is interlocked with the projection of the nailing strip of at least a fourth one of the plurality of siding panels located below and adjacent to the at least a first one of the plurality of siding panels. In some embodiments, the at least the third photovoltaic module overlays the nailing strip of the at least a first one of the plurality of siding panels and a fifth one of the plurality of siding panels, and wherein the exposed portion of the fifth one of the plurality of siding panels is adjacent to the second edge of the at least the third photovoltaic module.

In some embodiments, each of the plurality of siding panels is a vinyl siding panel. In some embodiments, each of the plurality of siding panels is composed of aluminum, fiber cement or wood. In some embodiments, the system further includes at least one wireway installed proximate to the first end of at least the first photovoltaic module. In some embodiments, the at least one wireway is installed between the first end of the first photovoltaic module and the second end of the second photovoltaic module.

In some embodiments, the exterior wall comprises a plurality of beams, the plurality of photovoltaic modules comprises at least a first photovoltaic module and a second photovoltaic module, ends of the first photovoltaic module and the second photovoltaic module abut against one another, thereby to form a seam, and the system further comprises: at least one flashing member, wherein the at least one flashing member is installed between the seam and at least one beam of the plurality of beams, wherein the at least one flashing member comprises at least one channel configured to flow water that leaks through the seam away from the at least one beam.

In some embodiments, the at least one flashing member comprises a plurality of channels, wherein each of the channels of the plurality of channels has at least one of a rectangular, triangular, or semicircular cross-sectional shape.

In some embodiments, a kit includes a plurality of photovoltaic modules configured to be installed on an exterior wall of a structure, wherein the photovoltaic modules are configured to be arranged in an array on the exterior wall, wherein each of the photovoltaic modules includes at least one solar cell, a first encapsulant encapsulating the at least one solar cell, wherein the first encapsulant includes a first surface and a second surface opposite the first surface, and a frontsheet juxtaposed with the first surface of the first encapsulant, wherein the frontsheet includes a glass layer; and a plurality of siding panels configured to be installed on the exterior wall, wherein the plurality of siding panels is configured to be installed adjacent to the plurality of photovoltaic modules.

In some embodiments, a method includes the steps of installing a plurality of photovoltaic modules on an exterior wall of a structure, wherein the photovoltaic modules are arranged in an array on the exterior wall, wherein each of the photovoltaic modules includes at least one solar cell, a first encapsulant encapsulating the at least one solar cell, wherein the first encapsulant includes a first surface and a second surface opposite the first surface, and a frontsheet juxtaposed with the first surface of the first encapsulant, wherein the frontsheet includes a glass layer; and installing a plurality of siding panels on the exterior wall, wherein the plurality of siding panels is adjacent to the plurality of photovoltaic modules.

In some embodiments, the present invention provides a system, comprising: a plurality of photovoltaic fence modules, wherein each of the plurality of photovoltaic fence modules comprises: a plurality of photovoltaic modules, wherein each of the photovoltaic modules includes at least one solar cell, an encapsulant encapsulating the at least one solar cell, wherein the encapsulant includes a first surface and a second surface opposite the first surface, and a first frontsheet juxtaposed with the first surface of the encapsulant, wherein the first frontsheet includes a first glass layer, and a second frontsheet juxtaposed with the second surface of the encapsulant, wherein the second frontsheet includes a second glass layer; a first rail; and a second rail, wherein the plurality of photovoltaic modules are installed between the first rail and the second rail.

In some embodiments, each of the photovoltaic fence modules comprises wiring connecting the plurality of photovoltaic modules to one another, and wherein the wiring extends within at least one of the first rail or the second rail.

### BRIEF DESCRIPTION OF THE DRAWINGS

FIGS. 1A and 1B are a top plan view and side elevational view, respectively, of some embodiments of a photovoltaic module;

FIGS. 2 and 3 are schematic views of some embodiments of a photovoltaic module;

FIG. 4 shows some embodiments of a building structure including a photovoltaic system comprising photovoltaic modules incorporated with building siding;

FIG. 5 shows some embodiments of photovoltaic modules integrated with building siding;

FIG. 6 is a side view of some embodiments of photovoltaic modules integrated with building siding;

FIG. 7 is a schematic view of some embodiments of photovoltaic modules integrated with building siding;

FIG. 8 illustrates some embodiments of a building structure including photovoltaic modules and building siding installed on beams of an exterior wall;

FIG. 9 is a schematic view of some embodiments of a building structure including photovoltaic modules and flashing members installed on beams of an exterior wall;

FIG. 10 is a schematic isometric view of some embodiments of a flashing member;

FIG. 11 is a schematic cross-sectional view of some embodiments of a flashing member;

FIG. 12 is a schematic cross-sectional view of some embodiments of a flashing member;

FIG. 13 is a schematic cross-sectional view of some embodiments of a flashing member; and

FIG. 14 shows some embodiments of a fencing system including photovoltaic modules.

### DETAILED DESCRIPTION

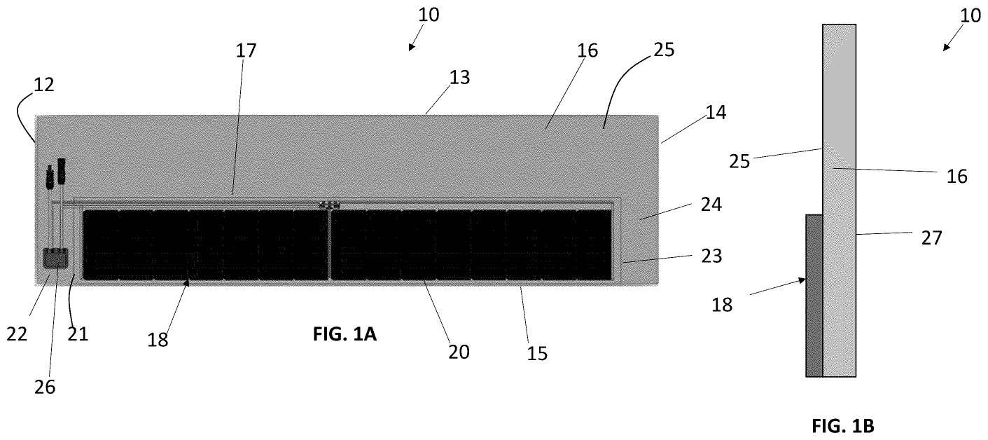

Referring to FIGS. 1A and 1B, in some embodiments, a photovoltaic module 10 includes a first end 12, a second end 14 opposite the first end 12, a first edge 13 extending from the first end 12 to the second end 14, and a second edge 15 opposite the first edge 13 and extending from the first end 12 to the second end 14. In some embodiments, the photovoltaic module 10 includes a headlap portion 16. In some embodiments, the headlap portion 16 extends from the first end 12 to the second end 14 and from the first edge 13 to a first location 17 between the first edge 13 and the second edge 15. In some embodiments, the photovoltaic module 10 includes a reveal portion 18. In some embodiments, the reveal portion 18 includes at least one solar cell 20. In some embodiments, the photovoltaic module 10 includes a first side lap 22 located at the first end 12. In some embodiments, the first side lap 22 includes a length extending from the first end 12 to a second location 21 between the first end 12 and the second end 14. In some embodiments, the photovoltaic module 10 includes a second side lap 24 located at the second end 14. In some embodiments, the second side lap 24 includes a length extending from the second end 14 to a third location 23 between the first end 12 and the second end 14. In some embodiments, the photovoltaic module 10 includes an outer surface 25 and an inner surface 27 opposite the outer surface 25. In some embodiments, the reveal portion 18 extends from the first side lap 22 to the second side lap 24 and from the second edge 15 to the first location 17. In some embodiments, the photovoltaic module 10 is configured to be installed on a building structure. In some embodiments, the photovoltaic module 10 is configured to be installed on an exterior wall of a building structure as described in further detail below. In some embodiments, at least one junction box 26 is located on the first side lap 22. In some embodiments, the at least one junction box 26 includes a plurality of the junction boxes 26. In some embodiments, the photovoltaic module 10 includes a structure, composition, components, and/or function similar to those of one or more embodiments of the photovoltaic modules disclosed in PCT International Patent Publication No. WO 2022/051593, Application No. PCT/US2021/049017, published Mar. 10, 2022, entitled Building Integrated Photovoltaic System, owned by GAF Energy LLC, the contents of which are incorporated by reference herein in its entirety.

In some embodiments, the at least one solar cell 20 includes a plurality of the solar cells 20. In some embodiments, the plurality of solar cells 20 includes two solar cells. In some embodiments, the plurality of solar cells 20 includes three solar cells. In some embodiments, the plurality of solar cells 20 includes four solar cells. In some embodiments, the plurality of solar cells 20 includes five solar cells. In some embodiments, the plurality of solar cells 20 includes six solar cells. In some embodiments, the plurality of solar cells 20 includes seven solar cells. In some embodiments, the plurality of solar cells 20 includes eight solar cells. In some embodiments, the plurality of solar cells 20 includes nine solar cells. In some embodiments, the plurality of solar cells 20 includes ten solar cells. In some embodiments, the plurality of solar cells 20 includes eleven solar cells. In some embodiments, the plurality of solar cells 20 includes twelve solar cells. In some embodiments, the plurality of solar cells 20 includes thirteen solar cells. In some embodiments, the plurality of solar cells 20 includes fourteen solar cells. In some embodiments, the plurality of solar cells 20 includes fifteen solar cells. In some embodiments, the plurality of solar cells 20 includes sixteen solar cells. In some embodiments, the plurality of solar cells 20 includes more than sixteen solar cells.

In some embodiments, the plurality of solar cells 20 is arranged in one row (i.e., one reveal). In another embodiment, the plurality of solar cells 20 is arranged in two rows (i.e., two reveals). In another embodiment, the plurality of solar cells 20 is arranged in three rows (i.e., three reveals). In another embodiment, the plurality of solar cells 20 is arranged in four rows (i.e., four reveals). In another embodiment, the plurality of solar cells 20 is arranged in five rows (i.e., five reveals). In another embodiment, the plurality of solar cells 20 is arranged in six rows (i.e., six reveals). In other embodiments, the plurality of solar cells 20 is arranged in more than six rows. In some embodiments, the at least one solar cell 20 is electrically inactive (i.e., a “dummy” solar cell).

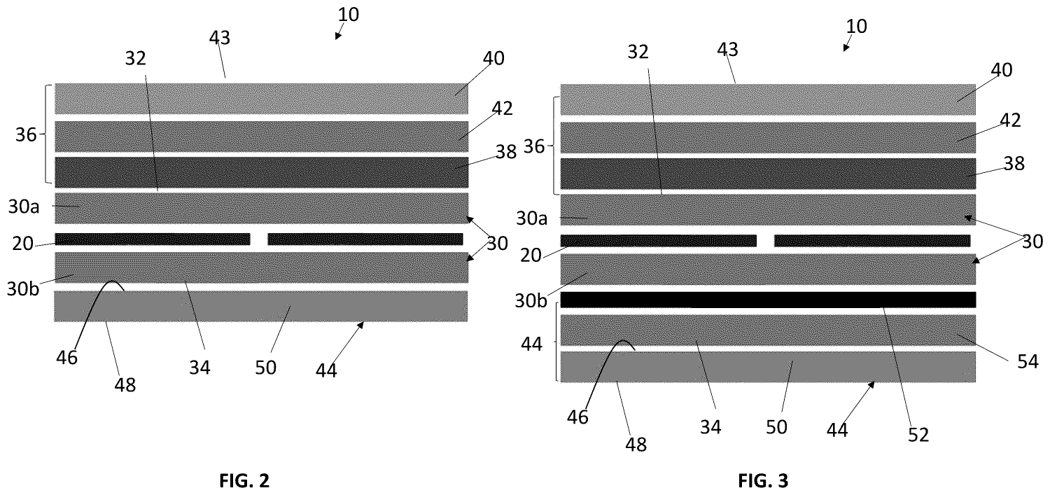

Referring to FIGS. 2 and 3, in some embodiments, the photovoltaic module 10 includes an encapsulant 30 encapsulating the at least one solar cell 20. In some embodiments, the encapsulant 30 includes a first layer 30a having a first surface 32 and a second layer 30b having a second surface 34 opposite the first surface 32. In some embodiments, the photovoltaic module 10 includes a frontsheet 36 juxtaposed with the first surface 32 of the first layer 30a of the encapsulant 30. In some embodiments, the frontsheet 36 includes a glass layer 38. In some embodiments, the frontsheet 36 includes a polymer layer 40 attached to the glass layer 38. In some embodiments, the polymer layer 40 forms an upper surface of the photovoltaic module 10. In some embodiments, the polymer layer 40 is attached to the glass layer 38 by a first adhesive layer 42. In some embodiments, an upper surface 43 of the polymer layer 40 is an upper surface of the photovoltaic module 10. In some embodiments, the upper surface 43 of the polymer layer 40 is textured. In some embodiments, the upper surface 43 of the polymer layer 40 is embossed. In some embodiments, the upper surface 43 of the polymer layer 40 is embossed with a plurality of indentations. In some embodiments, the upper surface 43 of the polymer layer 40 includes a pattern. In some embodiments, the upper surface 43 of the polymer layer 40 includes a printed pattern. In some embodiments, the upper surface 43 of the polymer layer 40 includes an embossed pattern. In some embodiments, the upper surface 43 of the polymer layer 40 includes a textured pattern.

In some embodiments, the photovoltaic module 10 includes a backsheet 44. In some embodiments, the backsheet 44 is juxtaposed with the second surface 34 of the second layer 30b of the encapsulant 30. In some embodiments, the backsheet 44 includes a first surface 46 and a second surface 48 opposite the first surface 46 of the backsheet 44. In some embodiments, the second surface 48 of the backsheet 44 forms a lower surface of the photovoltaic module 10. In some embodiments, the backsheet 44 includes a first layer 50. In some embodiments, the backsheet 44 includes a second layer 52 (see FIG. 3). In some embodiments, the second layer 52 is attached to the first layer 50 by a second adhesive layer 54. In some embodiments, the backsheet 44 includes only one layer (see FIG. 2). In some embodiments, the backsheet 44 includes only the first layer 50 (see FIG. 2). In some embodiments, the backsheet 44 does not include the second layer 52 (see FIG. 2). In some embodiments, the backsheet 44 is composed of a polymer. In some embodiments, the backsheet 44 is composed of thermoplastic polyolefin (TPO). In some embodiments, the backsheet 44 forms the headlap portion 16.

In some embodiments, the headlap portion 16 has a thickness of 1 mm to 10 mm. In some embodiments, the headlap portion 16 has a thickness of 2 mm to 10 mm. In some embodiments, the headlap portion 16 has a thickness of 3 mm to 10 mm. In some embodiments, the headlap portion 16 has a thickness of 4 mm to 10 mm. In some embodiments, the headlap portion 16 has a thickness of 5 mm to 10 mm. In some embodiments, the headlap portion 16 has a thickness of 6 mm to 10 mm. In some embodiments, the headlap portion 16 has a thickness of 7 mm to 10 mm. In some embodiments, the headlap portion 16 has a thickness of 8 mm to 10 mm. In some embodiments, the headlap portion 16 has a thickness of 9 mm to 10 mm. In some embodiments, the headlap portion 16 has a thickness of 1 mm to 9 mm. In some embodiments, the headlap portion 16 has a thickness of 2 mm to 9 mm. In some embodiments, the headlap portion 16 has a thickness of 3 mm to 9 mm. In some embodiments, the headlap portion 16 has a thickness of 4 mm to 9 mm. In some embodiments, the headlap portion 16 has a thickness of 5 mm to 9 mm. In some embodiments, the headlap portion 16 has a thickness of 6 mm to 9 mm. In some embodiments, the headlap portion 16 has a thickness of 7 mm to 9 mm. In some embodiments, the headlap portion 16 has a thickness of 8 mm to 9 mm. In some embodiments, the headlap portion 16 has a thickness of 1 mm to 8 mm. In some embodiments, the headlap portion 16 has a thickness of 2 mm to 8 mm. In some embodiments, the headlap portion 16 has a thickness of 3 mm to 8 mm. In some embodiments, the headlap portion 16 has a thickness of 4 mm to 8 mm. In some embodiments, the headlap portion 16 has a thickness of 5 mm to 8 mm. In some embodiments, the headlap portion 16 has a thickness of 6 mm to 8 mm. In some embodiments, the headlap portion 16 has a thickness of 7 mm to 8 mm.

In some embodiments, the headlap portion 16 has a thickness of 1 mm to 7 mm. In some embodiments, the headlap portion 16 has a thickness of 2 mm to 7 mm. In some embodiments, the headlap portion 16 has a thickness of 3 mm to 7 mm. In some embodiments, the headlap portion 16 has a thickness of 4 mm to 7 mm. In some embodiments, the headlap portion 16 has a thickness of 5 mm to 7 mm. In some embodiments, the headlap portion 16 has a thickness of 6 mm to 7 mm. In some embodiments, the headlap portion 16 has a thickness of 1 mm to 6 mm. In some embodiments, the headlap portion 16 has a thickness of 2 mm to 6 mm. In some embodiments, the headlap portion 16 has a thickness of 3 mm to 6 mm. In some embodiments, the headlap portion 16 has a thickness of 4 mm to 6 mm. In some embodiments, the headlap portion 16 has a thickness of 5 mm to 6 mm. In some embodiments, the headlap portion 16 has a thickness of 1 mm to 5 mm. In some embodiments, the headlap portion 16 has a thickness of 2 mm to 5 mm. In some embodiments, the headlap portion 16 has a thickness of 3 mm to 5 mm. In some embodiments, the headlap portion 16 has a thickness of 4 mm to 5 mm. In some embodiments, the headlap portion 16 has a thickness of 1 mm to 4 mm. In some embodiments, the headlap portion 16 has a thickness of 2 mm to 4 mm. In some embodiments, the headlap portion 16 has a thickness of 3 mm to 4 mm. In some embodiments, the headlap portion 16 has a thickness of 1 mm to 3 mm. In some embodiments, the headlap portion 16 has a thickness of 2 mm to 3 mm. In some embodiments, the headlap portion 16 has a thickness of 1 mm to 2 mm.

In some embodiments, the headlap portion 16 has a thickness of 1 mm. In some embodiments, the headlap portion 16 has a thickness of 2 mm. In some embodiments, the headlap portion 16 has a thickness of 3 mm. In some embodiments, the headlap portion 16 has a thickness of 4 mm. In some embodiments, the headlap portion 16 has a thickness of 5 mm. In some embodiments, the headlap portion 16 has a thickness of 6 mm. In some embodiments, the headlap portion 16 has a thickness of 7 mm. In some embodiments, the headlap portion 16 has a thickness of 8 mm. In some embodiments, the headlap portion 16 has a thickness of 9 mm. In some embodiments, the headlap portion 16 has a thickness of 10 mm.

In some embodiments, each of the encapsulant 30, the frontsheet 36, including each of the glass layer 38, the polymer layer 40, and the first adhesive layer 42, and the backsheet 44, including the first layer 50, the second layer 52, and the second adhesive layer 54 of the photovoltaic module 10, as applicable, includes a structure, composition and/or function of similar to those of more or one of the embodiments of the corresponding components disclosed in PCT International Patent Publication No. WO 2022/051593, Application No. PCT/US2021/049017, published Mar. 10, 2022, entitled Building Integrated Photovoltaic System, owned by GAF Energy LLC, the contents of which are incorporated by reference herein in its entirety.

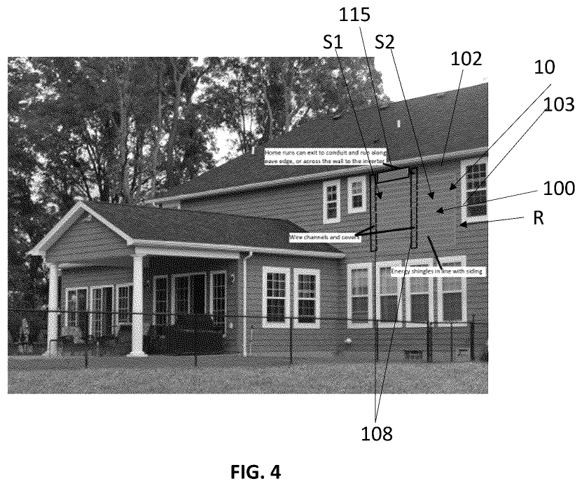

Referring to FIGS. 4 through 8, in some embodiments, the photovoltaic module 10 is configured to be a component of a photovoltaic system 100 installed on a wall 102 of a structure 103. In some embodiments, the exterior wall 102 is an exterior wall of the structure 103. In some embodiments, the exterior wall 102 is proximate to an external environment. In some embodiments, the structure 103 is a residential structure. In some embodiments, the structure 103 is a residential house. In some embodiments, the structure 103 is a commercial structure.

In some embodiments, the photovoltaic system 100 includes an underlayment layer 104 installed on the exterior wall 102. In some embodiments, the underlayment layer 104 is building paper. In some embodiments, the photovoltaic system 100 includes a plurality of the photovoltaic modules 10. In some embodiments, the plurality of photovoltaic modules 10 overlay the underlayment layer 104. In some embodiments, the photovoltaic modules 10 are arranged in an array on the exterior wall 102. In some embodiments, the array of the photovoltaic modules 10 includes subarrays S1, S2. In certain embodiments, the array includes more than the two subarrays S1, S2. In some embodiments, the array includes a single array. In some embodiments, each of the subarrays S1, S2 include a plurality of rows of the photovoltaic modules 10.

In some embodiments, the first side lap 22 of one of the photovoltaic modules 10 in the subarray S2 overlays the second side lap 24 of an adjacent another one of the photovoltaic modules 10 in the subarray S1 in the same one of the rows R. In some embodiments, the reveal portion 18 of one of the photovoltaic modules 10 in a subarray S1 overlays the headlap portion 16 of an adjacent another one of the photovoltaic modules 10 of the subarray S1. In some embodiments, the reveal portion 18 of one of the photovoltaic modules 10 in a subarray S2 overlays the headlap portion 16 of an adjacent another one of the photovoltaic modules 10 of the subarray S2.

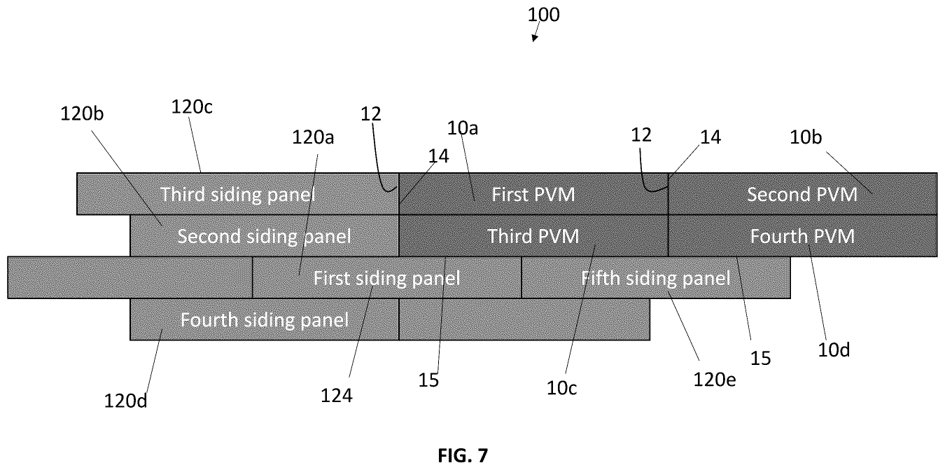

Referring to FIG. 7, in some embodiments, a first photovoltaic module 10a of the plurality of photovoltaic modules 10 is horizontally adjacent to a second photovoltaic module 10b of the plurality of photovoltaic modules 10. In some embodiments, a third photovoltaic module 10c of the plurality of photovoltaic modules 10 is vertically adjacent to the first photovoltaic module 10a. In some embodiments, a fourth photovoltaic module 10d of the plurality of photovoltaic modules 10 is horizontally adjacent to the third photovoltaic module 10c of the plurality of photovoltaic modules 10. In some embodiments, the fourth photovoltaic module 10d is vertically adjacent to the second photovoltaic module 10b.

In some embodiments, the first ends 12 of the first photovoltaic module 10a and the third photovoltaic module 10c are aligned with each other. In some embodiments, the second ends 14 of the first photovoltaic module 10a and the third photovoltaic module 10c are aligned with each other. In some embodiments, the first ends 12 of the first photovoltaic module 10a and the third photovoltaic module 10c are substantially aligned with each other. In some embodiments, the second ends 14 of the first photovoltaic module 10a and the third photovoltaic module 10c are substantially aligned with each other.

In some embodiments, the first ends 12 of the second photovoltaic module 10b and the fourth photovoltaic module 10d are aligned with each other. In some embodiments, the second ends 14 of the second photovoltaic module 10b and the fourth photovoltaic module 10d are aligned with each other. In some embodiments, the first ends 12 of the second photovoltaic module 10b and the fourth photovoltaic module 10d are substantially aligned with each other. In some embodiments, the second ends 14 of the second photovoltaic module 10b and the fourth photovoltaic module 10d are substantially aligned with each other.

In some embodiments, the first photovoltaic module 10a overlays at least a part of the headlap portion 16 of the third photovoltaic module 10c. In some embodiments, the reveal portion 18 of the first photovoltaic module 10a overlays at least a part of the headlap portion 16 of the third photovoltaic module 10c. In some embodiments, the reveal portion 18 of the first photovoltaic module 10a overlays a substantial portion of the headlap portion 16 of the third photovoltaic module 10c. In some embodiments, the second photovoltaic module 10b overlays at least a part of the headlap portion 16 of the fourth photovoltaic module 10d. In some embodiments, the reveal portion 18 of the second photovoltaic module 10b overlays at least a part of the headlap portion 16 of the fourth photovoltaic module 10d. In some embodiments, the reveal portion 18 of the second photovoltaic module 10b overlays a substantial portion of the headlap portion 16 of the fourth photovoltaic module 10d.

In some embodiments, the second photovoltaic module 10b overlays at least a part of the first photovoltaic module 10a. In some embodiments, the second photovoltaic module 10b overlays at least a part of the second side lap 24 of the first photovoltaic module 10a. In some embodiments, the first side lap 22 of the second photovoltaic module 10b overlays at least a part of the second side lap 24 of the first photovoltaic module 10a. In some embodiments, the fourth photovoltaic module 10d overlays at least a part of the third photovoltaic module 10c. In some embodiments, the fourth photovoltaic module 10d overlays at least a part of the second side lap 24 of the third photovoltaic module 10c. In some embodiments, the first side lap 22 of the fourth photovoltaic module 10d overlays at least a part of the second side lap 24 of the third photovoltaic module 10c.

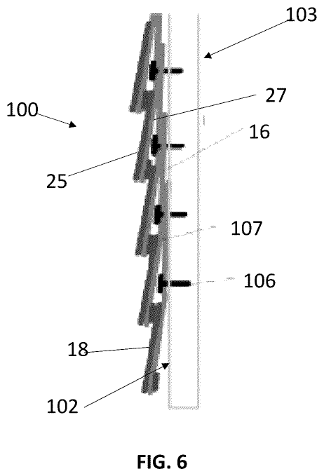

Referring to FIG. 6, in some embodiments, each of the photovoltaic modules 10 is installed on the exterior wall 102 by at least one fastener 106. In some embodiments, the at least one fastener 106 includes a plurality of the fasteners 106. In some embodiments, the at least one fastener 106 is a nail. In some embodiments, the at least one fastener 106 is a rivet. In some embodiments, the at least one fastener 106 is a screw. In some embodiments, the at least one fastener 106 is a bolt. In some embodiments, the at least one fastener 106 is a staple. In some embodiments, the at least one fastener 106 is a clip. In some embodiments, the headlap portion 16 is configured to receive the at least one fastener 106 therethrough. In some embodiments, the headlap portion 16 is penetrated by the at least one fastener 106. In some embodiments, the at least one fastener 106 is configured to maintain the photovoltaic module 10 in its installed position on the exterior wall 102.

In some embodiments, each of the photovoltaic modules 10 is installed on the exterior wall 102 by an adhesive. In some embodiments, the inner surface 27 includes the adhesive. In some embodiments, the adhesive is configured to maintain the photovoltaic module 10 in its installed position on the exterior wall 102.

In some embodiments, the inner surface 27 of one of the photovoltaic modules 10 is attached to the outer surface 25 of another of the photovoltaic modules 10. In some embodiments, the inner surface 27 of one of the photovoltaic modules 10 is attached to the outer surface 25 of another of the photovoltaic modules 10 by an adhesive 107.

In some embodiments, the inner surface 27 of the first photovoltaic module 10a is attached to the outer surface 25 of the third photovoltaic module 10c. In some embodiments, the inner surface 27 of the first photovoltaic module 10a is attached to the outer surface 25 of the third photovoltaic module 10c by THE adhesive. In some embodiments, the inner surface 27 of the first photovoltaic module 10a is attached to the outer surface 25 of the third photovoltaic module 10c module by at least one clip. In some embodiments, the at least one clip includes a plurality of the clips.

In some embodiments, the inner surface 27 of the second photovoltaic module 10b is attached to the outer surface 25 of the fourth photovoltaic module 10d. In some embodiments, the inner surface 27 of the second photovoltaic module 10b is attached to the outer surface 25 of the fourth photovoltaic module 10d by the adhesive 107. In some embodiments, the inner surface 27 of the second photovoltaic module 10b is attached to the outer surface 25 of the fourth photovoltaic module 10d module by the at least one clip.

Referring back to FIG. 4, in some embodiments, the overlay of the first and second side laps 22, 24 form at least one wireway 108. In some embodiments, the at least one wireway 108 is installed between the second ends 14 of the photovoltaic modules 10 in the first subarray S1 and the first ends 12 of the photovoltaic modules 10 in the second subarray S2. In some embodiments, the at least one wireway 108 is installed adjacent to the first ends 12 of the photovoltaic modules 10 in the first subarray S1. In some embodiments, the photovoltaic system 100 includes at least one jumper module 115. In some embodiments, the at least one jumper module 115 electrically connects the photovoltaic modules 10 of the first subarray S1 with the photovoltaic modules 10 of the second subarray S2. In some embodiments, the photovoltaic system 100, including the photovoltaic modules 10, the at least one jumper module 115, and the at least one wireway 108 include a structure, composition, function and/or an arrangement similar to those of one or more of the embodiments of the photovoltaic system and the photovoltaic modules, the jumper modules, and the wireways disclosed in PCT International Patent Publication No. WO 2022/051593, Application No. PCT/US2021/049017, published Mar. 10, 2022, entitled Building Integrated Photovoltaic System, owned by GAF Energy LLC, the contents of which are incorporated by reference herein in its entirety.

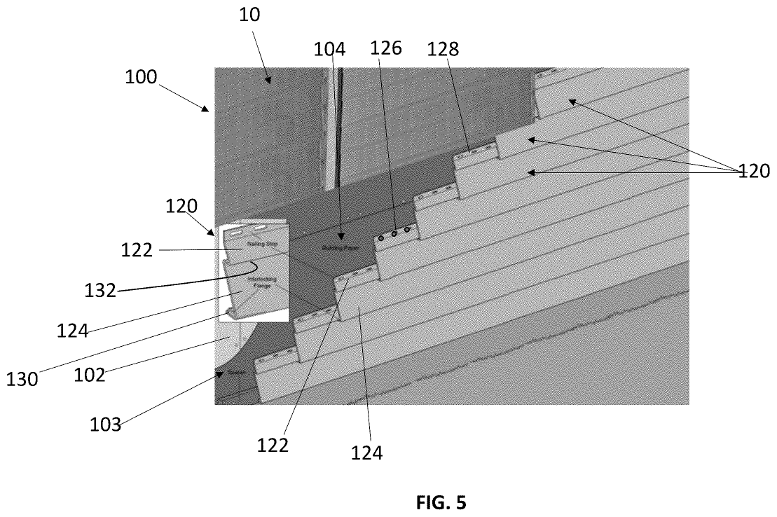

Referring to FIG. 5, in some embodiments, a plurality of siding panels 120 is installed on the exterior wall 102. In some embodiments, the plurality of siding panels 120 is installed adjacent to the photovoltaic modules 10. In some embodiments, each of the plurality of siding panels 120 is configured to be installed substantially horizontally on the exterior wall 102. In some embodiments, each of the plurality of siding panels 120 includes a nailing strip 122. In some embodiments, each of the plurality of siding panels 120 includes an exposed portion 124. In some embodiments, the exposed portion 124 is adjacent to the nailing strip 122. In some embodiments, each of the siding panels 120 is installed on the exterior wall 102 by at least one fastener 126. In some embodiments, the at least one fastener 126 includes a plurality of the fasteners 126. In some embodiments, the at least one fastener 126 is a nail. In some embodiments, the at least one fastener 126 is a rivet. In some embodiments, the at least one fastener 126 is a screw. In some embodiments, the at least one fastener 126 is a bolt. In some embodiments, the at least one fastener 126 is a staple. In some embodiments, the at least one fastener 126 is a clip. In some embodiments, the nailing strip 122 is configured to receive the at least one fastener 126 therethrough. In some embodiments, the nailing strip 122 is penetrated by the at least one fastener 126. In some embodiments, the nailing strip 122 includes a plurality of apertures 128. In some embodiments, each of the plurality of apertures 128 is sized and shaped to receive at least one of the fasteners 126. In some embodiments, the at least one fastener 126 is configured to maintain the siding panel 120 in its installed position on the exterior wall 102. In some embodiments, the exposed portion 124 of each of the plurality of siding panels 120 includes an interlocking flange 130. In some embodiments, the nailing strip 122 of each of the plurality of siding panels 120 includes a projection 132.

In some embodiments, each of the plurality of siding panels 120 is composed of plastic. In some embodiments, each of the plurality of siding panels 120 is composed of a polymer. In some embodiments, each of the plurality of siding panels 120 is a vinyl siding panel. In some embodiments, each of the plurality of siding panels 120 is composed of polyvinyl chloride (PVC). In some embodiments, each of the plurality of siding panels 120 is composed of aluminum. In some embodiments, each of the plurality of siding panels 120 is composed of fiber cement. In some embodiments, each of the plurality of siding panels 120 is composed of wood.

In some embodiments, the plurality of siding panels 120 includes at least a first siding panel 120a and a second siding panel 120b. In some embodiments, the plurality of siding panels 120 includes a third siding panel 120c. In some embodiments, the plurality of siding panels 120 includes a fourth siding panel 120d. In some embodiments, the plurality of siding panels 120 includes a fifth siding panel 120e. In some embodiments, the plurality of siding panels 120 includes more than five of the siding panels 120. In some embodiments, each of the plurality of siding panels 120 includes a length. In some embodiments, the lengths of each of the plurality of siding panels 120 are equal to one another. In some embodiments, the lengths of each of the plurality of siding panels 120 are substantially equal to one another. In some embodiments, the lengths of each of the plurality of siding panels 120 are different from one another. In some embodiments, the lengths of at least two of the plurality of siding panels 120 are equal to one another.

In some embodiments, at least a portion of the third photovoltaic module 10c overlays at least a portion of the first siding panel 120a. In some embodiments, at least a portion of the third photovoltaic module 10c overlays at least a portion of the nailing strip 122 of at least the first siding panel 120a. In some embodiments, at least a portion of the exposed portion 124 of the first siding panel 120a is adjacent to at least a portion of the second edge 15 of the third photovoltaic module 10c. In some embodiments, at least a portion of the third photovoltaic module 10c overlays at least a portion of the nailing strip 122 of the fifth siding panel 120e. In some embodiments, at least a portion of the fourth photovoltaic module 10d overlays at least a portion of the nailing strip 122 of at least a portion of the fifth siding panel 120e. In some embodiments, at least a portion of the exposed portion 124 of the fifth siding panel 120e is adjacent to at least a portion of the second edge 15 of at least the third photovoltaic module 10c.

In some embodiments, the fourth siding panel 120d is located below and adjacent to the first siding panel 120a. In some embodiments, at least a portion the interlocking flange 130 of at least the first siding panel 120a is interlocked with at least a portion of the projection 132 of the nailing strip 122 of the fourth siding panel 120d. In some embodiments, at least a portion the interlocking flange 130 of at least the first siding panel 120a is interlocked with at least a portion of the projection 132 of the nailing strip 122 of additional ones of the siding panels 120.

In some embodiments, the exposed portion 124 of at least the second siding panel 120b is aligned with the reveal portion 18 of the third photovoltaic module 10c. In some embodiments, the exposed portion 124 of at least the second siding panel 120b is substantially aligned with the reveal portion 18 of the third photovoltaic module 10c. In some embodiments, the exposed portion 124 of at least the third siding panel 120c is aligned with the reveal portion 18 of the first photovoltaic module 10a. In some embodiments, the exposed portion 124 of at least the third siding panel 120c is substantially aligned with the reveal portion 18 of the first photovoltaic module 10a. In some embodiments, the second siding panel 120b is interlocked with at least the first siding panel 120a. In some embodiments, the third siding panel 120c is interlocked with at least the second siding panel 120b.

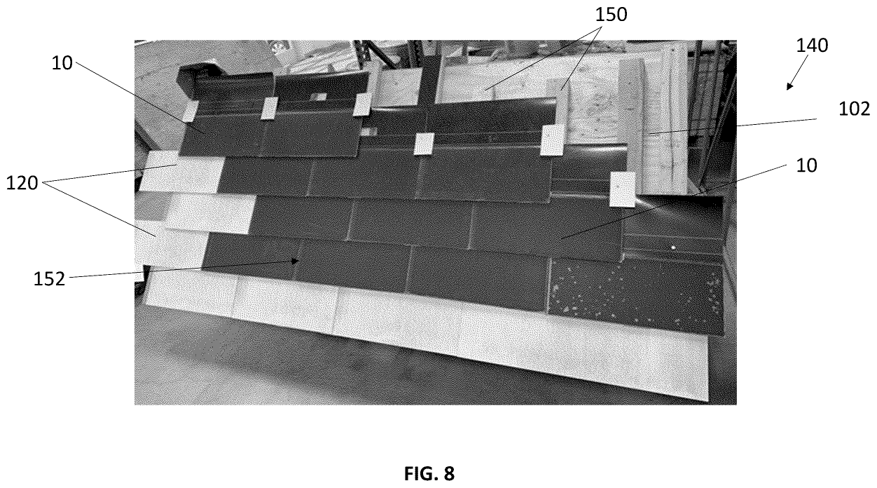

Referring to FIGS. 8 and 9, in some embodiments, a photovoltaic system 140 includes one or more of the photovoltaic modules 10 installed on the exterior wall 102 of the structure 103. As shown in the figure, in some embodiments, the exterior wall 102 includes a plurality of beams 150. In some embodiments, the beams 150 are wall joists. In some embodiments, the system 140 includes one or more of the siding panels 120 installed on the beams 150. In some embodiments, the system 140 includes the photovoltaic modules 10 and the siding panels 120 installed on the beams 150. In some embodiments, the system 140 includes one or more roofing shingles, such as non-photovoltaic roofing modules, cuttable roofing modules, and/or photovoltaic roofing modules, installed on a roof deck. In some embodiments, when the system 140 includes roofing shingles installed on the roof deck, the beams 150 are roof battens.

In some embodiments, ends of the photovoltaic modules 10 abut against one another, thereby defining one or more seams 152 therebetween. In some embodiments, the photovoltaic modules 10 are staggered, so that vertical butt joints are protected by the photovoltaic modules 10 below them. As shown in the figure, in some embodiments, the system 140 includes one or more flashing members 160 that are installed between the beams 150 and the photovoltaic modules 10, such that the flashing members 160 are under the seams 152. In some embodiments, the flashing members 160 are attached to the beams 150 by one or more fasteners, such as the fasteners 106. In some embodiments, the fasteners 106 are one or more of a nail, rivet, screw, bolt, staple, clip, and/or combinations thereof, as described. In some embodiments, the flashing members 160 are fastened to the beams 150 by an adhesive.

In some embodiments, the flashing members 160 direct water, such as but not limited to precipitation, which leaks through the seams 152, such that the water does not come into contact with the beams 150. In some embodiments, holes that are made in the flashing members 160 by the fasteners, such as the fasteners 106, are sealed with a sealant.

In some embodiments, the photovoltaic modules 10 are installed on the exterior wall 102 of the structure 103 with one or more fasteners, such as the fasteners 106. In some embodiments, the photovoltaic modules 10 are installed on the exterior wall 102 with one or more features that connect to one or more features of the flashing members 160. By way of non-limiting example, in some embodiments, the photovoltaic modules 10 and the flashing members 160 include cooperating protrusions and/or openings, which connect the photovoltaic modules 10 to the flashing members 160. In some embodiments, the photovoltaic modules 10 are connected to the beams 150 that are not located at the seams 152 by fasteners, such as the fasteners 106. Thus, in some embodiments, one or more of the fasteners 106 connect the headlap portions 16 of the photovoltaic modules 10, as shown in FIG. 1A and FIG. 1B and described above, to the beams 150 that are not located at the seams 152.

As shown in FIGS. 9-13, in some embodiments, the flashing member 160 includes one or more channels 162 to direct the water that leaks through the seams 152, away from the beams 150, such that the water does not come into contact with the beams 150. In some embodiments, each of the channels 162 includes a bottom channel portion 164 and side channel portions 166. In some embodiments, the side channel portions 166 are sized, shaped, located, and/or oriented, to prevent the water that is directed by the channels 162 from flowing over the side channel portions 166.

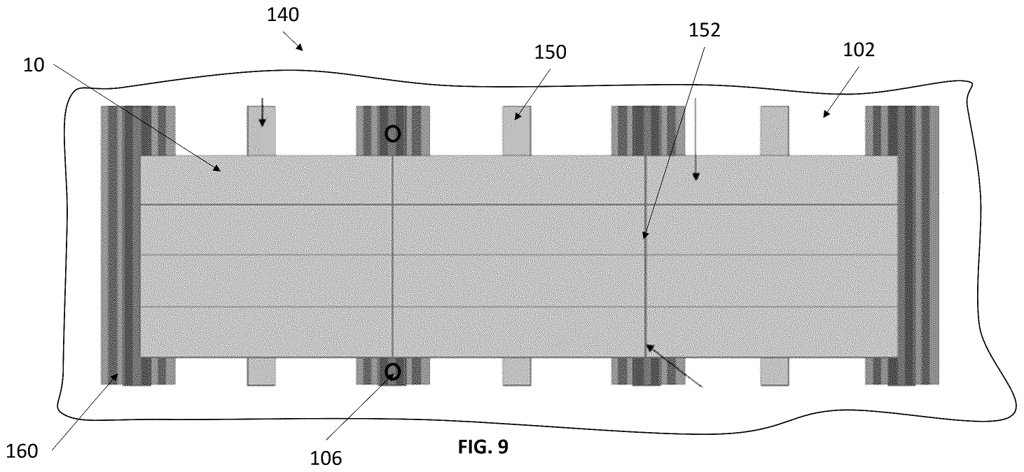

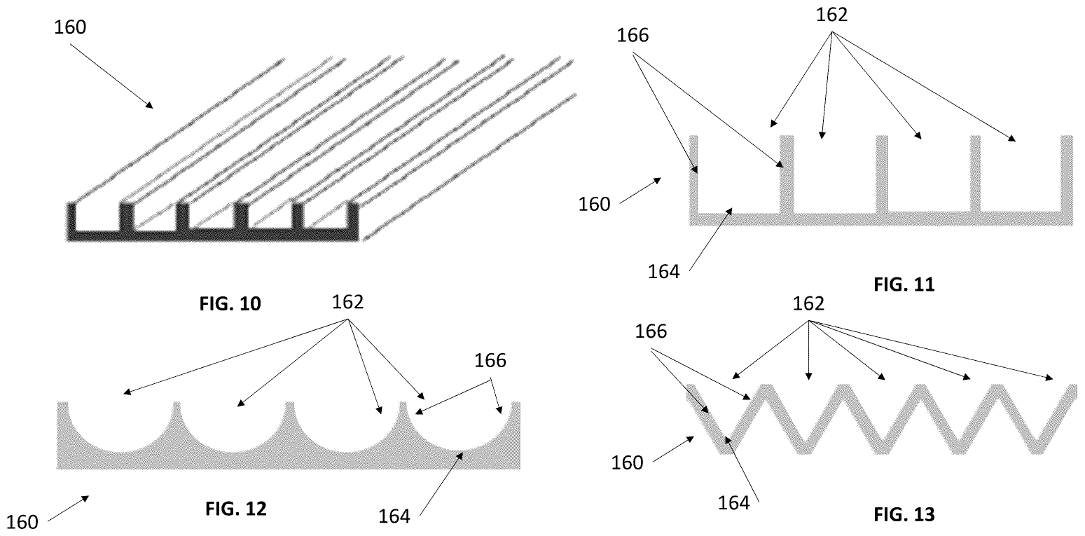

FIGS. 10, 11, 12, and 13 show some embodiments of the flashing members 160. As shown in the figures, in some embodiments, the channels 162 have generally rectangular, semicircular, or triangular cross-sectional shapes. In some embodiments, the channels 162 have other cross-sectional shapes, such as but not limited to square, oval, elliptical, polygonal, and/or other shapes.

In some embodiments, the flashing member 160 is 200 mm in length. In some embodiments, the flashing member 160 is 225 mm in length. In some embodiments, the flashing member 160 is 250 mm in length. In some embodiments, the flashing member 160 is 275 mm in length. In some embodiments, the flashing member 160 is 300 mm in length. In some embodiments, the flashing member 160 is 350 mm in length. In some embodiments, the flashing member 160 is 400 mm in length. In some embodiments, the flashing member 160 is 450 mm in length. In some embodiments, the flashing member 160 is 500 mm in length. In some embodiments, the flashing member 160 is 600 mm in length. In some embodiments, the flashing member 160 is 700 mm in length. In some embodiments, the flashing member 160 is 800 mm in length. In some embodiments, the flashing member 160 is 900 mm in length. In some embodiments, the flashing member 160 is 1000 mm in length. In some embodiments, the flashing member 160 is 1250 mm in length. In some embodiments, the flashing member 160 is 1500 mm in length. In some embodiments, the flashing member 160 is 1750 mm in length. In some embodiments, the flashing member 160 is 2000 mm in length. In some embodiments, the flashing member 160 is 2250 mm in length. In some embodiments, the flashing member 160 is 2500 mm in length.

In some embodiments, the flashing member 160 is more than 200 mm in length. In some embodiments, the flashing member 160 is more than 225 mm in length. In some embodiments, the flashing member 160 is more than 250 mm in length. In some embodiments, the flashing member 160 is more than 275 mm in length. In some embodiments, the flashing member 160 is more than 300 mm in length. In some embodiments, the flashing member 160 is more than 350 mm in length. In some embodiments, the flashing member 160 is more than 400 mm in length. In some embodiments, the flashing member 160 is more than 450 mm in length. In some embodiments, the flashing member 160 is more than 500 mm in length. In some embodiments, the flashing member 160 is more than 600 mm in length. In some embodiments, the flashing member 160 is more than 700 mm in length. In some embodiments, the flashing member 160 is more than 800 mm in length. In some embodiments, the flashing member 160 is more than 900 mm in length. In some embodiments, the flashing member 160 is more than 1000 mm in length. In some embodiments, the flashing member 160 is more than 1250 mm in length. In some embodiments, the flashing member 160 is more than 1500 mm in length. In some embodiments, the flashing member 160 is more than 1750 mm in length. In some embodiments, the flashing member 160 is more than 2000 mm in length. In some embodiments, the flashing member 160 is more than 2250 mm in length. In some embodiments, the flashing member 160 is more than 2500 mm in length.

In some embodiments, the flashing member 160 is less than 200 mm in length. In some embodiments, the flashing member 160 is less than 225 mm in length. In some embodiments, the flashing member 160 is less than 250 mm in length. In some embodiments, the flashing member 160 is less than 275 mm in length. In some embodiments, the flashing member 160 is less than 300 mm in length. In some embodiments, the flashing member 160 is less than 350 mm in length. In some embodiments, the flashing member 160 is less than 400 mm in length. In some embodiments, the flashing member 160 is less than 450 mm in length. In some embodiments, the flashing member 160 is less than 500 mm in length. In some embodiments, the flashing member 160 is less than 600 mm in length. In some embodiments, the flashing member 160 is less than 700 mm in length. In some embodiments, the flashing member 160 is less than 800 mm in length. In some embodiments, the flashing member 160 is less than 900 mm in length. In some embodiments, the flashing member 160 is less than 1000 mm in length. In some embodiments, the flashing member 160 is less than 1250 mm in length. In some embodiments, the flashing member 160 is less than 1500 mm in length. In some embodiments, the flashing member 160 is less than 1750 mm in length. In some embodiments, the flashing member 160 is less than 2000 mm in length. In some embodiments, the flashing member 160 is less than 2250 mm in length. In some embodiments, the flashing member 160 is less than 2500 mm in length.

In some embodiments, the flashing member 160 is 200 mm to 2500 mm in length. In some embodiments, the flashing member 160 is 225 mm to 2500 mm in length. In some embodiments, the flashing member 160 is 250 mm to 2500 mm in length. In some embodiments, the flashing member 160 is 275 mm to 2500 mm in length. In some embodiments, the flashing member 160 is 300 mm to 2500 mm in length. In some embodiments, the flashing member 160 is 350 mm to 2500 mm in length. In some embodiments, the flashing member 160 is 400 mm to 2500 mm in length. In some embodiments, the flashing member 160 is 450 mm to 2500 mm in length. In some embodiments, the flashing member 160 is 500 mm to 2500 mm in length. In some embodiments, the flashing member 160 is 600 mm to 2500 mm in length. In some embodiments, the flashing member 160 is 700 mm to 2500 mm in length. In some embodiments, the flashing member 160 is 800 mm to 2500 mm in length. In some embodiments, the flashing member 160 is 900 mm to 2500 mm in length. In some embodiments, the flashing member 160 is 1000 mm to 2500 mm in length. In some embodiments, the flashing member 160 is 1250 mm to 2500 mm in length. In some embodiments, the flashing member 160 is 1500 mm to 2500 mm in length. In some embodiments, the flashing member 160 is 1750 mm to 2500 mm in length. In some embodiments, the flashing member 160 is 2000 mm to 2500 mm in length. In some embodiments, the flashing member 160 is 2250 mm to 2500 mm in length.

In some embodiments, the flashing member 160 is 200 mm to 2000 mm in length. In some embodiments, the flashing member 160 is 225 mm to 2000 mm in length. In some embodiments, the flashing member 160 is 250 mm to 2000 mm in length. In some embodiments, the flashing member 160 is 275 mm to 2000 mm in length. In some embodiments, the flashing member 160 is 300 mm to 2000 mm in length. In some embodiments, the flashing member 160 is 350 mm to 2000 mm in length. In some embodiments, the flashing member 160 is 400 mm to 2000 mm in length. In some embodiments, the flashing member 160 is 450 mm to 2000 mm in length. In some embodiments, the flashing member 160 is 500 mm to 2000 mm in length. In some embodiments, the flashing member 160 is 600 mm to 2000 mm in length. In some embodiments, the flashing member 160 is 700 mm to 2000 mm in length. In some embodiments, the flashing member 160 is 800 mm to 2000 mm in length. In some embodiments, the flashing member 160 is 900 mm to 2000 mm in length. In some embodiments, the flashing member 160 is 1000 mm to 2000 mm in length. In some embodiments, the flashing member 160 is 1250 mm to 2000 mm in length. In some embodiments, the flashing member 160 is 1500 mm to 2000 mm in length. In some embodiments, the flashing member 160 is 1750 mm to 2000 mm in length.

In some embodiments, the flashing member 160 is 200 mm to 1500 mm in length. In some embodiments, the flashing member 160 is 225 mm to 1500 mm in length. In some embodiments, the flashing member 160 is 250 mm to 1500 mm in length. In some embodiments, the flashing member 160 is 275 mm to 1500 mm in length. In some embodiments, the flashing member 160 is 300 mm to 1500 mm in length. In some embodiments, the flashing member 160 is 350 mm to 1500 mm in length. In some embodiments, the flashing member 160 is 400 mm to 1500 mm in length. In some embodiments, the flashing member 160 is 450 mm to 1500 mm in length. In some embodiments, the flashing member 160 is 500 mm to 1500 mm in length. In some embodiments, the flashing member 160 is 600 mm to 1500 mm in length. In some embodiments, the flashing member 160 is 700 mm to 1500 mm in length. In some embodiments, the flashing member 160 is 800 mm to 1500 mm in length. In some embodiments, the flashing member 160 is 900 mm to 1500 mm in length. In some embodiments, the flashing member 160 is 1000 mm to 1500 mm in length. In some embodiments, the flashing member 160 is 1250 mm to 1500 mm in length.

In some embodiments, the flashing member 160 is 200 mm to 1250 mm in length. In some embodiments, the flashing member 160 is 225 mm to 1250 mm in length. In some embodiments, the flashing member 160 is 250 mm to 1250 mm in length. In some embodiments, the flashing member 160 is 275 mm to 1250 mm in length. In some embodiments, the flashing member 160 is 300 mm to 1250 mm in length. In some embodiments, the flashing member 160 is 350 mm to 1250 mm in length. In some embodiments, the flashing member 160 is 400 mm to 1250 mm in length. In some embodiments, the flashing member 160 is 450 mm to 1250 mm in length. In some embodiments, the flashing member 160 is 500 mm to 1250 mm in length. In some embodiments, the flashing member 160 is 600 mm to 1250 mm in length. In some embodiments, the flashing member 160 is 700 mm to 1250 mm in length. In some embodiments, the flashing member 160 is 800 mm to 1250 mm in length. In some embodiments, the flashing member 160 is 900 mm to 1250 mm in length. In some embodiments, the flashing member 160 is 1000 mm to 1250 mm in length.

In some embodiments, the flashing member 160 is 200 mm to 1000 mm in length. In some embodiments, the flashing member 160 is 225 mm to 1000 mm in length. In some embodiments, the flashing member 160 is 250 mm to 1000 mm in length. In some embodiments, the flashing member 160 is 275 mm to 1000 mm in length. In some embodiments, the flashing member 160 is 300 mm to 1000 mm in length. In some embodiments, the flashing member 160 is 350 mm to 1000 mm in length. In some embodiments, the flashing member 160 is 400 mm to 1000 mm in length. In some embodiments, the flashing member 160 is 450 mm to 1000 mm in length. In some embodiments, the flashing member 160 is 500 mm to 1000 mm in length. In some embodiments, the flashing member 160 is 600 mm to 1000 mm in length. In some embodiments, the flashing member 160 is 700 mm to 1000 mm in length. In some embodiments, the flashing member 160 is 800 mm to 1000 mm in length. In some embodiments, the flashing member 160 is 900 mm to 1000 mm in length.

In some embodiments, the flashing member 160 is 200 mm to 900 mm in length. In some embodiments, the flashing member 160 is 225 mm to 900 mm in length. In some embodiments, the flashing member 160 is 250 mm to 900 mm in length. In some embodiments, the flashing member 160 is 275 mm to 900 mm in length. In some embodiments, the flashing member 160 is 300 mm to 900 mm in length. In some embodiments, the flashing member 160 is 350 mm to 900 mm in length. In some embodiments, the flashing member 160 is 400 mm to 900 mm in length. In some embodiments, the flashing member 160 is 450 mm to 900 mm in length. In some embodiments, the flashing member 160 is 500 mm to 900 mm in length. In some embodiments, the flashing member 160 is 600 mm to 900 mm in length. In some embodiments, the flashing member 160 is 700 mm to 900 mm in length. In some embodiments, the flashing member 160 is 800 mm to 900 mm in length.

In some embodiments, the flashing member 160 is 200 mm to 800 mm in length. In some embodiments, the flashing member 160 is 225 mm to 800 mm in length. In some embodiments, the flashing member 160 is 250 mm to 800 mm in length. In some embodiments, the flashing member 160 is 275 mm to 800 mm in length. In some embodiments, the flashing member 160 is 300 mm to 800 mm in length. In some embodiments, the flashing member 160 is 350 mm to 800 mm in length. In some embodiments, the flashing member 160 is 400 mm to 800 mm in length. In some embodiments, the flashing member 160 is 450 mm to 800 mm in length. In some embodiments, the flashing member 160 is 500 mm to 800 mm in length. In some embodiments, the flashing member 160 is 600 mm to 800 mm in length. In some embodiments, the flashing member 160 is 700 mm to 800 mm in length.

In some embodiments, the flashing member 160 is 200 mm to 700 mm in length. In some embodiments, the flashing member 160 is 225 mm to 700 mm in length. In some embodiments, the flashing member 160 is 250 mm to 700 mm in length. In some embodiments, the flashing member 160 is 275 mm to 700 mm in length. In some embodiments, the flashing member 160 is 300 mm to 700 mm in length. In some embodiments, the flashing member 160 is 350 mm to 700 mm in length. In some embodiments, the flashing member 160 is 400 mm to 700 mm in length. In some embodiments, the flashing member 160 is 450 mm to 700 mm in length. In some embodiments, the flashing member 160 is 500 mm to 700 mm in length. In some embodiments, the flashing member 160 is 600 mm to 700 mm in length.

In some embodiments, the flashing member 160 is 200 mm to 600 mm in length. In some embodiments, the flashing member 160 is 225 mm to 600 mm in length. In some embodiments, the flashing member 160 is 250 mm to 600 mm in length. In some embodiments, the flashing member 160 is 275 mm to 600 mm in length. In some embodiments, the flashing member 160 is 300 mm to 600 mm in length. In some embodiments, the flashing member 160 is 350 mm to 600 mm in length. In some embodiments, the flashing member 160 is 400 mm to 600 mm in length. In some embodiments, the flashing member 160 is 450 mm to 600 mm in length. In some embodiments, the flashing member 160 is 500 mm to 600 mm in length.

In some embodiments, the flashing member 160 is 200 mm to 500 mm in length. In some embodiments, the flashing member 160 is 225 mm to 500 mm in length. In some embodiments, the flashing member 160 is 250 mm to 500 mm in length. In some embodiments, the flashing member 160 is 275 mm to 500 mm in length. In some embodiments, the flashing member 160 is 300 mm to 500 mm in length. In some embodiments, the flashing member 160 is 350 mm to 500 mm in length. In some embodiments, the flashing member 160 is 400 mm to 500 mm in length. In some embodiments, the flashing member 160 is 450 mm to 500 mm in length.

In some embodiments, the flashing member 160 is 200 mm to 450 mm in length. In some embodiments, the flashing member 160 is 225 mm to 450 mm in length. In some embodiments, the flashing member 160 is 250 mm to 450 mm in length. In some embodiments, the flashing member 160 is 275 mm to 450 mm in length. In some embodiments, the flashing member 160 is 300 mm to 450 mm in length. In some embodiments, the flashing member 160 is 350 mm to 450 mm in length. In some embodiments, the flashing member 160 is 400 mm to 450 mm in length.

In some embodiments, the flashing member 160 is 200 mm to 400 mm in length. In some embodiments, the flashing member 160 is 225 mm to 400 mm in length. In some embodiments, the flashing member 160 is 250 mm to 400 mm in length. In some embodiments, the flashing member 160 is 275 mm to 400 mm in length. In some embodiments, the flashing member 160 is 300 mm to 400 mm in length. In some embodiments, the flashing member 160 is 350 mm to 400 mm in length.

In some embodiments, the flashing member 160 is 200 mm to 350 mm in length. In some embodiments, the flashing member 160 is 225 mm to 350 mm in length. In some embodiments, the flashing member 160 is 250 mm to 350 mm in length. In some embodiments, the flashing member 160 is 275 mm to 350 mm in length. In some embodiments, the flashing member 160 is 300 mm to 350 mm in length.

In some embodiments, the flashing member 160 is 200 mm to 300 mm in length. In some embodiments, the flashing member 160 is 225 mm to 300 mm in length. In some embodiments, the flashing member 160 is 250 mm to 300 mm in length. In some embodiments, the flashing member 160 is 275 mm to 300 mm in length.

In some embodiments, the flashing member 160 is 200 mm to 275 mm in length. In some embodiments, the flashing member 160 is 225 mm to 275 mm in length. In some embodiments, the flashing member 160 is 250 mm to 275 mm in length.

In some embodiments, the flashing member 160 is 200 mm to 250 mm in length. In some embodiments, the flashing member 160 is 225 mm to 250 mm in length. In some embodiments, the flashing member 160 is 225 mm to 250 mm in length.

In some embodiments, the flashing member 160 has a width of less than 50 mm. In some embodiments, the flashing member 160 has a width of less than 60 mm. In some embodiments, the flashing member 160 has a width of less than 70 mm. In some embodiments, the flashing member 160 has a width of less than 80 mm. In some embodiments, the flashing member 160 has a width of less than 90 mm. In some embodiments, the flashing member 160 has a width of less than 100 mm. In some embodiments, the flashing member 160 has a width of less than 110 mm. In some embodiments, the flashing member 160 has a width of less than 120 mm. In some embodiments, the flashing member 160 has a width of more than 120 mm.

In some embodiments, the flashing member 160 has a height of less than 5 mm. In some embodiments, the flashing member 160 has a height of less than 6 mm. In some embodiments, the flashing member 160 has a height of less than 7 mm. In some embodiments, the flashing member 160 has a height of less than 8 mm. In some embodiments, the flashing member 160 has a height of less than 9 mm. In some embodiments, the flashing member 160 has a height of less than 10 mm. In some embodiments, the flashing member 160 has a height of less than 11 mm. In some embodiments, the flashing member 160 has a height of less than 12 mm. In some embodiments, the flashing member 160 has a height of more than 12 mm.

In some embodiments, a width or diameter of the channels 162, such as between the side channel portions 166, is less than 5 mm. In some embodiments, a width or diameter of the channels 162 is less than 10 mm. In some embodiments, a width or diameter of the channels 162 is less than 15 mm. In some embodiments, a width or diameter of the channels 162 is less than 20 mm. In some embodiments, a width or diameter of the channels 162 is less than 25 mm. In some embodiments, a width or diameter of the channels 162 is less than 30 mm.

In some embodiments, the flashing member 160 comprises a polymer. In some embodiments, the flashing member 160 comprises a cuttable material.

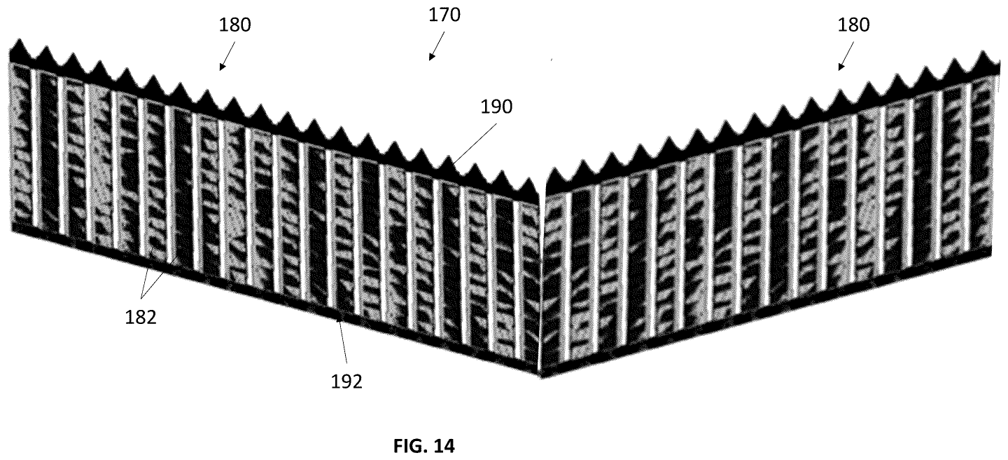

With reference to FIG. 14, a photovoltaic fencing system 170 includes a plurality of photovoltaic fence modules 180. In some embodiments, one or more of the photovoltaic fence modules 180 includes one or more photovoltaic modules 182. In some embodiments, the modules 182 include one or more components of the photovoltaic modules 10. In some embodiments, the photovoltaic modules 182 includes the at least one solar cell 20 and the encapsulant 30 that encapsulates the at least one solar cell 20, such as is shown in FIG. 2 and FIG. 3 and is described above. In some embodiments, the photovoltaic module 182 include one or more layers of the frontsheet 36, such as one or more of the polymer layer 40, the first adhesive layer 42, and/or the glass layer 38. In some embodiments, the frontsheet 36 covers at least one face of the encapsulant 30. In some embodiments, the photovoltaic module 182 is a bifacial module, with active solar cells on both sides. In some embodiments, the photovoltaic module 182 includes two of the frontsheets 36 one frontsheet 36 that covers one face of the encapsulant 30, and another frontsheet 36 that covers the opposite face of the encapsulant 30. Thus, in some embodiments, the photovoltaic module 182 may be formed, for example, by removing the backsheet 44 from the photovoltaic module 10, and covering the surface of the encapsulant 30 exposed by removing the backsheet 44 with another frontsheet 36.

In some embodiments, the solar fence module 180 includes a first rail 190 and a second rail 192. In some embodiments, either or both of the first rail 190 and/or the second rail 192 may retain the plurality of the photovoltaic modules 182, thereby providing the photovoltaic fence modules 180. In some embodiments, either or both of the first rail 190 and/or the second rail 192 may retain wiring that connects the photovoltaic modules 182 to one another, and/or to one or more other components that connect to an electrical system of a structure that the photovoltaic fencing system 170 surrounds. In some embodiments, the first rail 190 and/or the second rail 192 may be provided in different lengths, thereby to provide the photovoltaic fence modules 180 of different lengths. In some embodiments, the first rail 190 may be connectable to one or more other first rails 190, and/or the second rail 192 may be connectable to one or more other second rails 192, thereby to provide the photovoltaic fence modules 180 of different lengths.

As shown in the figure, in some embodiments, the photovoltaic fencing system 170 may include a plurality of the solar fence modules 180 extending in different directions, and each of the solar fence modules 180 includes two surfaces that convert light, such as sunlight, into electricity.

In some embodiments, a kit includes a plurality of the photovoltaic modules 10 and a plurality of the siding panels 120. In some embodiments, the kit includes the at least one jumper module 115.

In some embodiments, a kit include a plurality of the photovoltaic modules 10 and/or a plurality of the siding panels 120, and a plurality of the flashing members 160.

In some embodiments, a kit includes a plurality of the solar fence modules 180.

In some embodiments, a method comprises the steps of:
installing the plurality of photovoltaic modules 10 on the exterior wall 102 of the structure 103, wherein the photovoltaic modules 10 are arranged in an array on the exterior wall 102; and
installing the plurality of siding panels 120 on the exterior wall 102, wherein the plurality of siding panels 120 is installed adjacent to the plurality of photovoltaic modules 10.

In some embodiments, a method comprises the steps of:
installing the plurality of photovoltaic modules 10 on the exterior wall 102 of the structure 103, with a plurality of flashing members 160 therebetween; and/or
installing the plurality of siding panels 120 on the exterior wall 102, with a plurality of flashing members 160 therebetween.

In some embodiments, a method comprises the steps of:
installing the plurality of photovoltaic modules 10 on the roof deck, with a plurality of flashing members 160 therebetween; and/or
installing the plurality of roofing shingles on the roof deck, with a plurality of flashing members 160 therebetween.

What is claimed is:

1. A system, comprising:
a plurality of photovoltaic modules installed on an exterior wall of a structure,
wherein the photovoltaic modules are arranged in an array on the exterior wall,
wherein each of the photovoltaic modules includes
at least one solar cell,
a first encapsulant encapsulating the at least one solar cell,
wherein the first encapsulant includes a first surface and a second surface opposite the first surface, and
a frontsheet juxtaposed with the first surface of the first encapsulant,
wherein the frontsheet includes
a glass layer; and
a plurality of siding panels installed on the exterior wall,
wherein the plurality of siding panels is adjacent to the plurality of photovoltaic modules.

2. The system of claim 1, wherein each of the plurality of photovoltaic modules includes:
a first end,
a second end opposite the first end,
a first edge extending from the first end to the second end, and
a second edge opposite the first edge and extending from the first end to the second end,
a headlap portion,
wherein the headlap portion extends from the first end to the second end and from the first edge to a first location between the first edge and the second edge.

3. The system of claim 2, wherein each of the plurality of photovoltaic modules is installed on the exterior wall by at least one fastener, and wherein the headlap portion is configured to receive the at least one fastener therethrough.

4. The system of claim 1, wherein a first photovoltaic module of the plurality of photovoltaic modules is horizontally adjacent to a second photovoltaic module of the plurality of photovoltaic modules, and wherein a third photovoltaic module of the plurality of photovoltaic modules is vertically adjacent to the first photovoltaic module.

5. The system of claim 4, wherein the first ends of the first and third photovoltaic modules are substantially aligned with each other, wherein the second ends of the first and third photovoltaic modules are substantially aligned with each other, wherein the first photovoltaic module overlays at least a part of the headlap portion of the third photovoltaic module.

6. The system of claim 5, wherein each of the plurality of photovoltaic modules includes an outer surface and an inner surface opposite the outer surface, and wherein the inner surface of the first photovoltaic module is attached to the outer surface of the third photovoltaic module.

7. The system of claim 5, wherein each of the plurality of siding panels is installed substantially horizontally on the exterior wall, and wherein at least the third photovoltaic module overlays at least a portion of at least a first one of the plurality of siding panels.

8. The system of claim 7, wherein each of the plurality of siding panels includes a nailing strip and an exposed portion adjacent to the nailing strip, wherein the at least the third photovoltaic module overlays the nailing strip of the at least a first one of the plurality of siding panels, and wherein the exposed portion of the at least a first one of the plurality of siding panels is adjacent to the second edge of the at least the third photovoltaic module.

9. The system of claim 8, wherein each of the plurality of photovoltaic modules includes a reveal portion, and wherein the exposed portion of at least a second one of the plurality of siding panels is substantially aligned with the reveal portion of the third photovoltaic module.

10. The system of claim 9, wherein the exposed portion of at least a third one of the plurality of siding panels is substantially aligned with the reveal portion of the first photovoltaic module.

11. The system of claim 9, wherein the exposed portion of each of the plurality of siding panels includes an interlocking flange, wherein the nailing strip of each of the plurality of siding panels includes a projection, and wherein the interlocking flange of the at least first one of the plurality of siding panels is interlocked with the projection of the nailing strip of at least a fourth one of the plurality of siding panels located below and adjacent to the at least a first one of the plurality of siding panels.

12. The system of claim 8, wherein the at least the third photovoltaic module overlays the nailing strip of the at least a first one of the plurality of siding panels and a fifth one of the plurality of siding panels, and wherein the exposed portion of the fifth one of the plurality of siding panels is adjacent to the second edge of the at least the third photovoltaic module.

13. The system of claim 1, wherein each of the plurality of siding panels is composed of vinyl, aluminum, fiber cement or wood.

14. The system of claim 1, wherein each of the plurality of photovoltaic modules includes a side lap portion, and
wherein the second photovoltaic module overlays at least a part of the side lap of the first photovoltaic module.

15. The system of claim 5, further comprising at least one wireway installed proximate to the first end of at least the first photovoltaic module.

16. The system of claim 1, wherein the exterior wall comprises a plurality of beams, wherein the plurality of photovoltaic modules comprises at least a first photovoltaic module and a second photovoltaic module, wherein ends of the first photovoltaic module and the second photovoltaic module abut against one another, thereby to form a seam, wherein the system further comprises:
at least one flashing member,
wherein the at least one flashing member is installed between the seam and at least one beam of the plurality of beams.
wherein the at least one flashing member comprises at least one channel configured to flow water that leaks through the seam away from the at least one beam.

17. The system of claim 16, wherein the at least one flashing member comprises a plurality of channels, wherein each of the channels of the plurality of channels has at least one of a rectangular, triangular, or semicircular cross-sectional shape.

18. A kit, comprising:
a plurality of photovoltaic modules configured to be installed on an exterior wall of a structure,
wherein the photovoltaic modules are configured to be arranged in an array on the exterior wall,
wherein each of the photovoltaic modules includes
at least one solar cell,
a first encapsulant encapsulating the at least one solar cell,
wherein the first encapsulant includes a first surface and a second surface opposite the first surface, and
a frontsheet juxtaposed with the first surface of the first encapsulant,
wherein the frontsheet includes
a glass layer; and
a plurality of siding panels configured to be installed on the exterior wall,
wherein the plurality of siding panels is configured to be installed adjacent to the plurality of photovoltaic modules.

19. A system, comprising:
a plurality of photovoltaic fence modules, wherein each of the plurality of photovoltaic fence modules comprises:
a plurality of photovoltaic modules,
wherein each of the photovoltaic modules includes
at least one solar cell,
an encapsulant encapsulating the at least one solar cell,
wherein the encapsulant includes a first surface and a second surface opposite the first surface, and
a first frontsheet juxtaposed with the first surface of the encapsulant,
wherein the first frontsheet includes
°a first glass layer, and
a second frontsheet juxtaposed with the second surface of the encapsulant,
wherein the second frontsheet includes
°a second glass layer;
a first rail; and
a second rail,
wherein the plurality of photovoltaic modules are installed between the first rail and the second rail.

20. The system of claim 19, wherein each of the photovoltaic fence modules comprises wiring connecting the plurality of photovoltaic modules to one another, and wherein the wiring extends within at least one of the first rail or the second rail.
